(19) United States
(12) Patent Application Publication
(10) Pub. No.: US 2017/0245325 A1
(43) Pub. Date: Aug. 24, 2017

(54) Intelligently Powered Devices

(71) Applicants: John Arthur Fee, Garland, TX (US); Louis F. Perez, Mesquite, TX (US)

(72) Inventors: John Arthur Fee, Garland, TX (US); Louis F. Perez, Mesquite, TX (US)

(21) Appl. No.: 15/405,264

(22) Filed: Jan. 12, 2017

Related U.S. Application Data
(60) Provisional application No. 62/279,504, filed on Jan. 15, 2016.

(51) Int. Cl. H05B 3/36; B60N 2/56; A47C 7/74; H03K 9/06; H03K 9/08

(52) U.S. Cl. CPC H05B 3/36; H03K 9/06; H03K 9/08; A47C 7/748; B60N 2/5678; H02J 7/0013

(57) ABSTRACT

A device, such as a heated seat cushion device, is provided. Circuitry and other components are used to regulate, control and/or switch electrical power to an electrical element, such as a heating element, of the device. The device may regulate the energy delivered to the electrical element by a processor on an intelligent energy management platform. Accordingly, power may be routed to the electrical element of the heated device in a controlled manner. Control may include turning on and off the power, providing pulsed power, and modulating the power and/or pulsed power delivered to the electrical element.

### CLAIM OF PRIORITY AND CROSS-REFERENCE TO RELATED APPLICATION

The present application is related to U.S. Provisional Patent Application No. 62/279,504, filed Jan. 15, 2016, entitled “Intelligent Heated Cushion.” The present application hereby claims priority under 35 U.S.C. §119(e) to U.S. Provisional Patent Application No. 62/279,504.

### TECHNICAL FIELD

The invention generally relates to intelligent energy delivery and intelligently powered devices. For example, certain embodiments relate to heating systems and methods for heating devices with a controlled and managed heating process, which may, for example, use pulsing and novel feedback circuitry to control heating. More specifically, the invention relates to a controlled system and method for heating consumer apparatuses and clothing, such as, for example, seat cushions. It should be recognized, however, that the inventive aspects can be applied to any devices for controlling and managing energy delivery.

### BACKGROUND

There exists a myriad of reasons why human beings need heat, especially when the environment provides other than ideal temperatures. For centuries humans have used passive methods to provide insulation from the cold and it has only been recently that active methods have been used to provide warmth. Heated devices have been around for a long time. Most of these devices, however, have their shortcomings and pitfalls. Specifically, for example, heated cushions usually require an alternate heater or other source to heat them and these devices are tethered to a particular area and are not mobile. So many times, heated cushions are not flexible in their use and are tied to specific applications such as heated car seats, for example. Also, heated devices, even if mobile, do not control or manage energy delivery. Energy is simply provided to a heating element without adjusting the energy delivery based on any criteria. Also, energy delivery (and thus heat, for example) is not customized in any way. Therefore, heating of the device is not configured for specific applications. For instance, with respect to heated seat cushions, heat is delivered to a zone without regard to the user's body location or the user's preferences. At most, a user can select between different heat levels (e.g., low, medium and high), but the user cannot customize or select heating zones, or heating with respect to any particular zone. Typical heated devices also inefficient due to the manner in which the device is heated without regard to any feedback or heating requirements within the heating cycle.

### SUMMARY

In order to provide flexibility to the user, where a heated device can be used in any kind of application, a method and apparatus is needed to provide an intelligent and feature-rich heated device, such as a portable or fixed-location device (e.g., a heated seat cushion). When designed and used properly, this will provide improved service over a much wider variety of uses.

Again, it should be understood that the concepts provided herein can be used in any application for which there is energy delivery. This includes both heating and cooling applications. This also includes energy delivery to a wide variety of devices such as fixed or mobile devices, seat cushions, seats (e.g., car seats), clothing products (e.g., pants, jackets, socks, hats, etc.), medical devices, blankets, pet beds, and any other device that has energy delivered to it (e.g., for heating or cooling purposes).

In one example embodiment, a device with efficient power routing is provided. The device includes a cover, an interior material disposed within the cover, an electrical element disposed within the cover, a first power source connected to the electrical element, and operable to deliver energy to the electrical element, and an intelligent energy management platform connected to the first power source and the electrical element. The intelligent energy management platform selectively causes an interruption of energy from the first power source to the electrical element.

In another example embodiment, a heated seat cushion is provided. The cushion includes an outer cover, an interior material disposed within the outer cover, a heating element disposed within the outer cover, a first power source connected to the heating element, and operable to deliver energy to the heating element, and an intelligent energy management platform connected to said the first power source and the heating element. The intelligent energy management platform selectively causes an interruption of energy from the first power source to the heating element.

It should be recognized that these are example embodiments only. Various components may be rearranged, substituted, omitted, and or added, as desired.

### BRIEF DESCRIPTION OF THE DRAWINGS

The novel features believed characteristic of the present invention are set forth in the appended claims. However, the invention itself, as well as a preferred mode of use, further objectives and advantages thereof, will be best understood by reference to the following detailed description of an illustrative embodiment when read in conjunction with the accompanying drawings wherein.

FIG. 1 is a schematic of a circuit for intelligent energy delivery in accordance with an example embodiment;

FIG. 2 is an illustration of a heating cycle and pulsed energy delivery during the heating cycle in accordance with an example embodiment;

FIG. 3 is an illustration of pulsed energy delivery by way of pulse width modulation in accordance with an example embodiment;

FIG. 4 is an illustration of pulsed energy delivery by way of pulse frequency modulation in accordance with an example embodiment;

FIG. 5 is an illustration of pulsed energy delivery by way of pulse time modulation in accordance with an example embodiment;

FIG. 6 is a top view of an intelligent heated seat cushion in accordance with an example embodiment;

FIG. 7 is a top view of an intelligent heated seat cushion in accordance with an example embodiment;

FIG. 8 is a top view of an intelligent heated seat cushion in accordance with an example embodiment;

FIG. 9 is a side, cross-sectional view of an intelligent heated seat cushion in accordance with an example embodiment;

FIG. 10 is a block diagram depicting various components within an intelligent energy management platform in accordance with an example embodiment; and

FIG. 11A and FIG. 11B are a schematic of circuitry for use in delivering energy to a device in accordance with an example embodiment.

### DETAILED DESCRIPTION

The present invention relates to a system and method for heating devices. While certain example embodiments are generally related to a heated seat cushion device, the heating circuitry, and the systems, components, and methods described herein may be applied to other devices, such as, for example, clothing, blankets, and pet beds. The inventive aspects herein can be used for any suitable energy delivery scenario including both heating and cooling applications, for example. At least some embodiments relate to control circuitry for controlling the electrical components of a powered (e.g., heated) element.

At least some embodiments further relate to a heated seat cushion device typically used for comfort and outdoor events. As an example, the heating system and method can be incorporated into and/or used to heat a heated seat cushion device. When electrically activated, these appliances virtually always route electrical power to the heating element(s). Semiconducting switching devices are used to regulate, control and/or switch electrical power to the heating element. In at least one embodiment, the heated device regulates the heat generated in the heating element by an active switching device. Feedback is obtained from strategically placed sensors (e.g., thermistors) and delivered to and/or received by an intelligent energy management platform. Heating of the device is controlled and managed in an efficient manner wherein pulsed energy is delivered to a heating element and the pulsed energy is adjusted for certain criteria such as, for example, the state of the heating cycle, the location of heating elements within the device and the capacity of an energy source (e.g., a chargeable battery) used to power the device. Preheating of the device is provided in certain embodiments, which can result in saving capacity of an internal, mobile power source. Accordingly, the presently disclosed system and method routes power in a controlled manner to regulate the temperature of the cushion.

The heated cushion can be designed and used in many different ways including a seated heat cushion, a pillow for the bed or the couch, or uses in the automobile such as a heated seat cushion. Myriad other applications exist, including, but not limited to, fishing or camping devices and clothing, or other such applications. Because of the portability of the device, the same concepts and circuitry can used almost anywhere for extended periods of time.

In at least some embodiments, the device is a passive device in that it does not require any moving parts such as a motor blower or any other such air moving components, thereby saving energy. Therefore, the gain bandwidth product to minimize overshoot of the power electronic circuit response time and corresponding temperature regulation can be adjusted specifically for the intelligent heated cushion application, which will provide quicker heat times and energy savings. In addition a 7.2V 18650 battery type with different capacities such as 2.2, 2.8, or 3.4 Ah may be used. The terminal voltage may be 7.2V li-ion and the microprocessor terminal voltage may be 3.7 volts. These are merely examples, however, and it should be recognized that different specific components of the device and the circuitry therein can be substituted to take advantage of the management and control aspects of energy delivery discussed herein.

In at least some embodiments, the device possesses many different intelligent electrical and thermal capabilities which enhance its use. For example, the intelligent cushion possesses a microprocessor, a voltage regulator, power switching, one or more rechargeable batteries, battery monitor(s), a thermistor or infrared sensing device, a debug port, and PID controller logic.

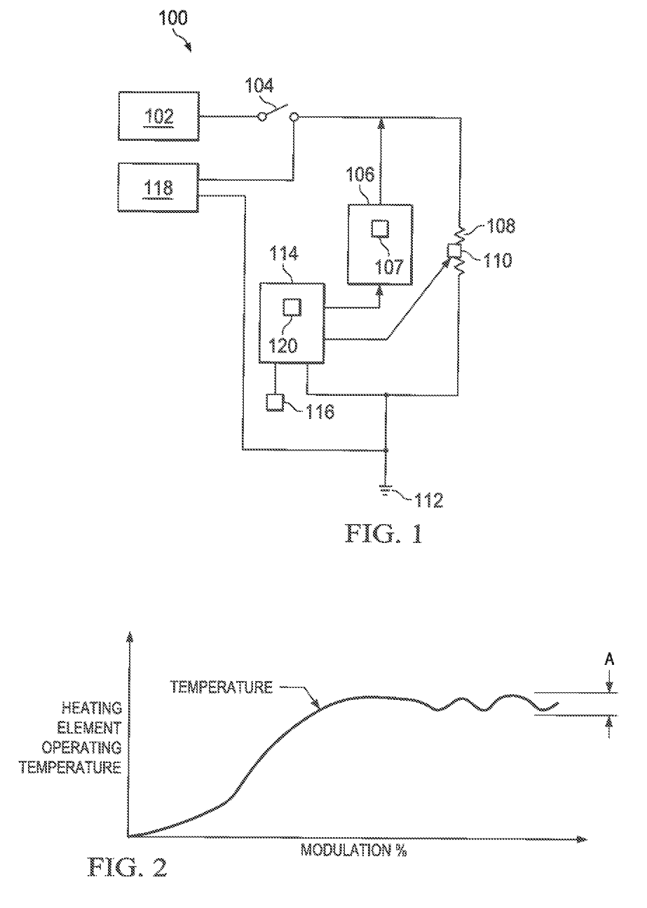

FIG. 1 illustrates a schematic of a circuit for intelligent energy delivery in accordance with an example embodiment. Circuit 100 includes a first (preferably internal) energy source 118, which may, for example, be a rechargeable battery. First energy source 118 may be any suitable energy source and can include multiple batteries or battery packs. Source 118 can be fixed capacity (e.g., non-rechargeable batteries) or variable capacity (e.g., rechargeable batteries). Source 118, while preferred to be mobile and/or self-contained, may also be fixed (e.g., house current through a wall plug, cigarette lighter, A/C, D/C, etc.). In this specific example, first energy source 118 is a mobile, self-contained, rechargeable battery or battery pack. Source 118 delivers energy across circuit 100 (and its various components via connection on one side to a switch point and connection on the other side to ground 112. Circuit 100 also includes a second (preferably external) power source 102. Like source 118, source 102 may include an AC or DC power supply of any suitable configuration. Source 118 is connected to circuit 100 via switch 104. Preferably, source 102 is detachable from a device that includes the remaining circuit components, such that said device may be mobile or transportable.

Circuit 100 further includes in intelligent energy management platform 114. Further details of platform 114 are discussed elsewhere herein. However, it should be understood that platform 114 provides control and management of energy delivery to a device containing one or more elements of circuit 100 and, more specifically to a load 108 (discussed further herein). Intelligent energy management platform 114 includes processor 120, which contains the intelligence needed for efficient and customizable energy delivery. Processor 120 may be any suitable processor including, for example, a microprocessor on a printed circuit board (PCB).

Circuit 100 also includes a power source monitor 116. Monitor 116 preferably can monitor any number of power source criteria such as, for example, voltage and/or current levels of any power source used with, or connected to, circuit 100. For example, monitor 116 may, in certain embodiments, monitor the battery level, battery temperature for safety, output, charge level, voltage, current, or other criteria associated with power source 118. Monitor 116 is preferably connected to platform 114 such that the values and data obtained by monitor 116 may be used by platform 114 to properly control and efficiently manage energy delivery (e.g., delivery of energy from sources 102 and/or 118).

Circuit 100 also includes a load 108. Load 108 is powered by either or both of sources 102 and 118. Load 108 may be any suitable load including, for example, a passive or active element. In certain example embodiments, load 108 is a resistive heating element or an infrared laser bulb within a heated device (e.g., a heated seat cushion). Load 108 may also comprise a ceramic heating element to provide long term heat storage, which is especially useful for the preheat function. While not expressly shown as separate, the ceramic heating element may be the load 108 or may be a separately provided element within the circuit and within the device utilizing the circuit.

Circuit 110 also includes one more sensors 110 which can be, for example, thermistors. Preferably, a thermistor 110 is disposed on, or adjacent to, load 108. In certain embodiments, thermistor 110 or infrared sensing device can sense criteria (e.g., temperature) associated with load 108 and deliver or otherwise make available such information to platform 114. This information may be used by platform 114 to control and/or manage delivery of energy to load 108 and/or other components of circuit 100 or a device using circuit 100.

Circuit 100 further includes a current and/or voltage source 106. Source 106 provides controlled voltage and/or current to circuit 100 as managed by platform 114. Preferably, source 106 includes regulator 107 (e.g., a current and/or voltage regulator).

In certain embodiments, intelligent energy management platform 114 provides one or more of a number of different functions. These may include, for example:

(1) communicating with sensor(s) 100;

(2) monitoring and/or adjusting power source criteria (e.g., by way of monitor 116);

(3) interpreting different switching configurations in a device using circuit 100;

(4) controlling, regulating, monitoring, or otherwise managing current and/or voltage provided, for example, by current/voltage source 106;

(5) managing regulator 107;

(6) providing a platform for processor 120 and the various control circuitry, algorithms (e.g., pulsed power algorithms), etc. contained therein;

(7) controlling various functions of circuit 100 or a device using circuit 100 (e.g., controlling a pre-heat function);

(8) controlling and/or monitoring various components of circuit 100 including, for example, power sources 102 and 118;

(9) providing charging logic for efficiently charging source 118;

(10) providing safety mechanisms for various components of circuit 100 and/or a device using circuit 100 (e.g., recognizing and reacting to components becoming too hot or receiving too much current from a power source);

(11) providing battery protection functionality; and

(12) providing multiple heating levels (e.g., off/on, low, medium and high) for the heating element(s).

These are example functions only and it should be recognized that platform 114 may be configured to provide any one or more of these functions, or other functions, needed for controlling and/or managing circuit components, load components, and/or energy delivery.

Preferably, platform 114 (and/or processor 120) provides intelligence for delivering pulsed power (e.g., from source 118) to load 108). In at least some embodiments, pulsed energy is delivered. Pulsed energy provides efficient power in order to get load 108 (for example) to full operating temperature. Energy delivery by a typical, fixed-level supply wastes energy and unnecessarily reduces capacity of an internal power source such as a rechargeable battery. As illustrated in FIG. 2, for example, pulsed power during the heating process can be used to ensure the most efficient use of energy. Moreover, adjustment of the pulsed power supply provides even more efficiency in the delivery of energy. During the initial phases of the heating cycle (e.g., as illustrated toward the left of the graph in FIG. 2), pulse modulation at a higher percentage (i.e., more energy) is used to heat the element/device more quickly. As the heating cycle approaches peak or desired temperature, however, less energy or pulsed power percentage is required to bring the element/device up to full heat. Therefore, in the latter stages of the heating cycle, the pulse (or modulation) percentage may be reduced. Once full heat has been achieved, the pulse modulation percentage may be raised and lowered to keep the operating temperature within a desired range (e.g., range A). The heating cycle may be more generically referred to as the powering cycle of the heating element (or of any suitable electrical element). Again, it should be noted that this concept may be applied in cooling applications and other energy delivery applications.

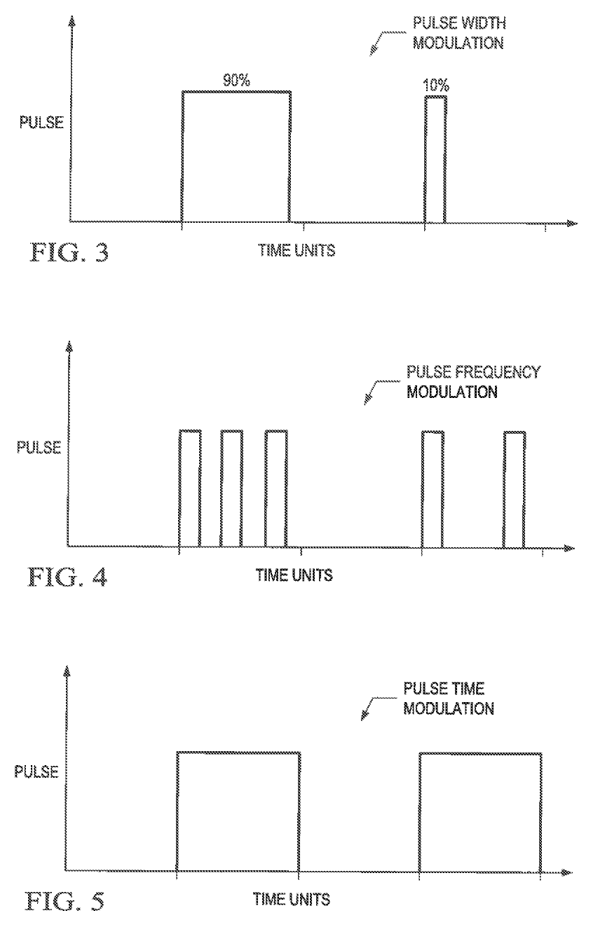

In certain embodiments, modulation of the pulsed power is accomplished by way of pulse width modulation. This is further illustrated in FIG. 3. Energy is delivered in time units or duty cycles. In one time unit, there might be no energy provided. In the next time unit, a pulse of energy is delivered. In FIG. 2, the first energy pulse is shown at 90% (i.e., 90 percent of the width of one time unit). Relatively high width pulses may be used, for example, in the earlier stages of the heating cycle. In a next time unit, there is again no energy delivery. Then, in a next time cycle, there is another pulse of energy. FIG. 3 illustrates that in this time unit, the pulse is at 10% (i.e., 10 percent of the width of a time unit). This illustrates the concept of modulating the pulse (or, in this case, the pulse width) of the power supply as the heating cycle progresses). It should be understood that the pulse width may be changed or modulated from time unit to time unit or in a few cases may be held constant for one or more time units. It should also be understood that the pulse percentage may be adjusted upward or downward depending on the desired heating configuration and other criteria such as desired power usage, power savings, and acceptable range of temperature, and variable and/or programmable times required to reach operating temperature upon initial powering the device, as the heating element heats and cools during heating and heat dissipation through use of the device employing the heating element.

In other embodiments, pulse power modulation may be achieved by way of pulse frequency modulation as shown in FIG. 4. According to this power delivery method, both pulse widths and time units remain constant, while the number of pulses in a given time unit and/or the space between pulses is varied.

In still other embodiments, pulse power modulation may be achieved by way of pulse time modulation. This is illustrated, for example, in FIG. 5. According to this method, when an energy pulse is provided, it is provided for an entire time unit. However, the length of the time units may be varied to, in effect, provide for varying amounts of energy at different times. It should be understood that these various methods of modulation (as well as any other suitable modulation method) may be employed in order to vary the amount of energy delivered by a power source to the load.

In certain applications and/or embodiments, the intelligent energy management platform may be used to adjust the state of charge of the battery in connection with the discharge rate. For example, as the state of charge of the internal power supply changes, one can change the modulation duty cycle and/or the type of modulation and/or the discharge rate of the battery. In still other embodiments, one can change the pulse type (or duty cycle) as a function of one or more criteria associated with, or received from, sensors, thermistors, power supplies and heating elements.

As previously discussed, the concept of modulated, pulsed power delivery may be used in any number of heating and/or cooling applications and in connection with any suitable device. In one example device, modulated, pulsed power is provided to a heated seat cushion as illustrated in FIG. 6. Cushion 602, while shown in a generally square shape, may have any desired shape. Cushion 602 includes one more heating zones, such as heating zone 604. A heating zone is created by the provision of one or more heating elements 608. In the illustrated embodiment, a heating element 608 is a resistive wire arranged in a serpentine configuration. Element 608, however, may comprise any desired element or material arranged in any desired or suitable configuration. Heating element 608 is shown connected to an intelligent energy management platform 610, which may comprise one or more of the components described elsewhere herein (e.g., platform 114 in FIG. 1). Heating element 608 is shown connected to platform 610 by way of connectors 612, which may comprise any suitable connectors depending on the type of element and the configuration and placement of the energy management platform, for example. One or more sensors (e.g., thermistors) 606 may be strategically positioned in order to obtain device/element information (e.g., temperature of the heating element in one or more locations) and provide that information back to the intelligent energy management platform 610 (connection to platform not expressly shown). In some cases, a single thermistor may be sufficient, such as one thermistor placed centrally within a zone. In other cases, it may be desirable to position multiple thermistors in various locations within one or more zones in order to improve the accuracy of data collection as well as provide the capability of customizing the control of energy delivery to different portions of a zone and/or to different zones. When multiple thermistors are provided, a corresponding switching system (not expressly shown) may likewise be provided in order to allow control thermistors individually and/or in different combinations. Multiple thermistors also provides for thermistor control according to what may be called the “voting rule.” That is, if one thermistor, for example, is detecting a colder temperature than a second thermistor, an element associated with the first (cooler) thermistor may be heated at the expense of an element associated with the second (hotter) thermistor.

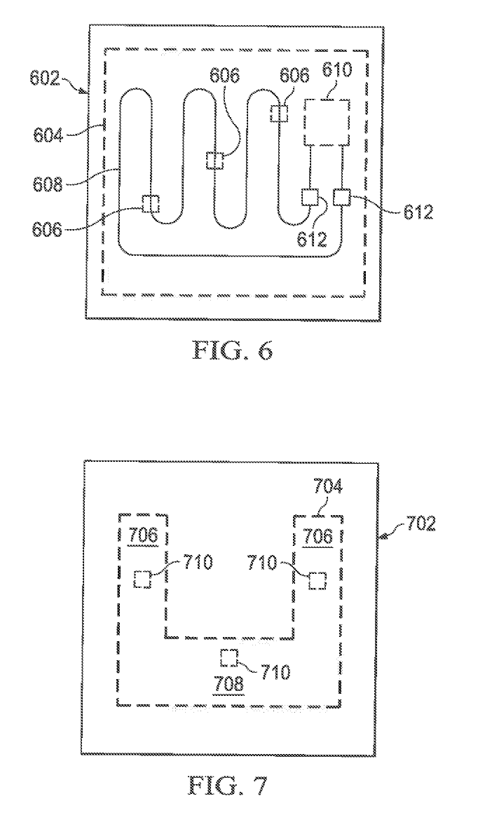

FIG. 7 illustrates a customized zone 704 within a cushion 702. Zone 704 may be customized, for example, to correspond to body parts of a user. Zone 704 is shown as having two similar subzones 706 connected by a larger connecting subzone 708. In this example, subzones 706 might correspond to a user's legs when seated on the seat cushion, while subzone 708 might correspond to a user's seat. Again, one or more sensors (e.g., thermistors) 710 are employed to deliver feedback to the energy management platform. In this case, sensors 710 may be used to customize higher heating of subzones 706 while simultaneously causing relatively lower heating of subzone 708 and save energy. This should be understood as an example only. Any level of configuration and customization may be achieved depending on a number of factors including, without limitation, the number and placement of sensors, the number and positioning of zones and subzones, the number and positioning of heating elements within zones and subzones, and the intelligence provided by the energy management platform. Also, it will be understood that different zones and zone configurations may be desirable depending on the specific application. Blankets might have multiple heating zones to accommodate feet versus upper body and/or to accommodate differing preferences of sleeping partners. Jackets might have different zones for arms, torso, neck, etc. Socks might have different zones for toes, foot top, foot bottom and ankles. Thus, one may switch between zones/thermistors or combinations of zones/thermistors. These are meant as illustrative examples only.

FIG. 8 illustrates multiple, user selectable, individual zones within a heated seat cushion. Each zone 804 within cushion 802 preferably has at least one associated sensor 810. As with other example embodiments described herein, modifications may be made to zone shape and positioning, the number and positioning of sensors, and the number and positioning of heating elements, in order to achieved the desired customization of the heating experience enjoyed by the user.

In addition, additional thermal storage mediums exist such as liquid gel (medical type) or liquid filled pliable heat containers which store heat longer. Using heat storage mediums are particularly useful when using pre-heat where the liquid medium (or other type of thermal storage medium) can provide many more BTU's of heat for a much longer time and since pre-heat is not draining the battery, these stored BTU's provide much longer run times.

FIG. 9 illustrates a side, cross-sectional view of an intelligent heated seat cushion in accordance with an example embodiment. Preferably, cushion 900 comprises a number of different layers designed to enhance the functionality and the heating experience of the cushion. Cushion 900 includes an outer layer 904. Outer layer 904 provides a housing and base platform for the other layers and components of cushion 900. Outer layer 904 may comprise any suitable material such as cloth, canvas, solid or semi-solid materials, foam and the like. Preferably, outer layer 904 provides protection for the other components and layers such as waterproofing and or water resistance or camouflaging. Inward from outer layer 904 lies an insulation layer 906. Insulation layer 906 may be connected to outer layer 904 (e.g., by stitching) or may fit freely and independently within outer layer 904. Insulation layer 906 may provide insulation (either outwardly or inwardly). Insulation on the bottom of cushion 900, for example, may provide for insulating the bottom of the cushion from cold outer temperatures, thereby improving the heating function for the top of cushion 900. Heating element 908 is shown disposed inwardly (down from the top) of an upper insulation layer 906. Preferably, a reflective layer 910 is provided beneath (downwardly from the top) heating element 908. Preferably, an infrared reflective layer 910 is upwardly reflecting thus saving energy (or, in other words, reflects heat in the direction of intended heating for a user or in the same direction that heat from the heating element 908 is intended to be delivered). Thus, preferably, infrared reflectively layer 910 is disposed from element 908 in a direction opposite that of intended heat dissipation. Also shown is an intelligent energy management platform 914 within a platform receiving chamber 912. Chamber 912 may be formed by suitable stitching and/or the use of additional materials or layers, for example. Preferably, chamber 912 secures electrical platform 914 within the boundaries of cushion 900 so that platform 914 is basically a part of the cushion device and is transportable with the cushion. Preferably, platform 914 is removable from chamber 912 so that it can be maintained independently from the cushion. Also, when removed (or when disposed within chamber 912), platform 914 may be used to charge the internal power source and/or manage or monitor different components of the heating and/or intelligence circuitry. Preferably, platform 914 has a pair of external leads (not expressly shown) for connection to external components, such as an external power supply for example. Interior space 916 (as well as spaces between layers) may comprise additional layers of additional materials or empty space. It should be understood that one or more layers may be duplicated, omitted, or changed in their orientation with respect to one another in order to achieve varying functionality such as different cushioning, wear, and heating characteristics. It should also be understood that FIG. 9 is an example of a heated seat cushion application. Similar layering and components may be employed when the heating platform is used in different applications such as blankets, car seats, pet beds and clothing, for example.

FIG. 9 also illustrates an additional layer, or top layer 916. Preferably, top layer 916 is connectable in a flap configuration such that one edge of layer 916 is attached to an edge of the upper outer layer 904 of cushion 900. Thus, layer 916 may be folded over to cover cushion 900 or folded back to uncover cushion 900. Preferably, top layer 916 is removable (e.g., by way of a Velcro® connection). Layer 916 may also be secured to cushion 900 along multiple edges such that it does not fold over or back. Top layer 916 provides added insulation for a user to enhance the user's heating experience (e.g., if the cushion is too hot without the top layer). Top layer 916 may be formed of different materials, multiple layers, and varying or various R-values to provide differing insulation characteristics as desired. Top layer 916 may also provide breathing, wicking, waterproofing or other characteristics that may be desired by a user.

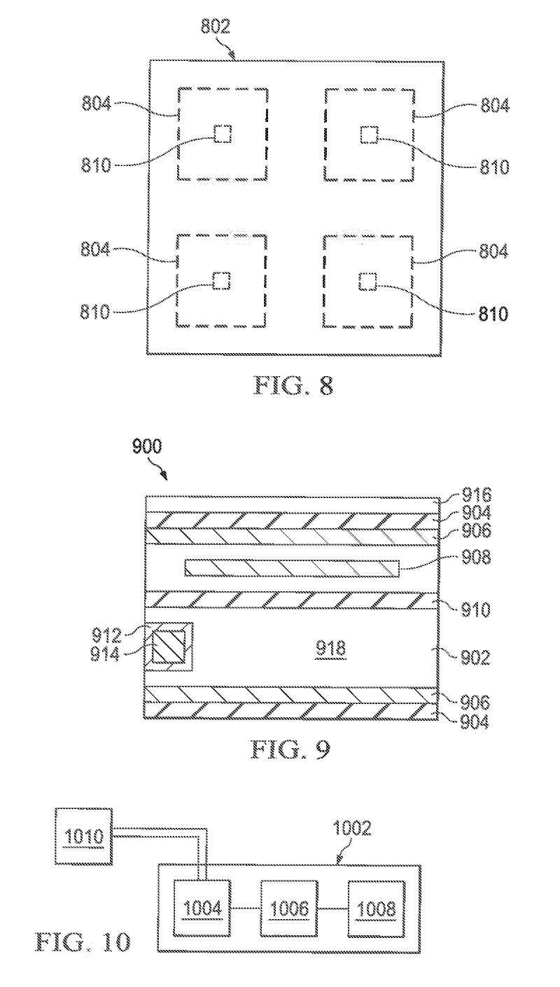

FIG. 10 is a block diagram depicting various components within an intelligent energy management platform in accordance with an example embodiment. Platform 1002 includes internal power supply 1004, processor 1006 and switching device 1008. External leads may be provided as shown (and as described elsewhere herein) to connect internal power supply 1004 and/or other components of platform 1002 to one or more external power sources 1010. The components are illustrative only and may be arranged and interconnected in any suitable manner. For example, internal power supply 1004 may be independent of the structure of the remainder of platform 1002.

Preferably, as already described, the intelligent energy management platform is connectable to an external power source. This provides several advantages. For example, an external power supply may be used to provide all or part of the heating (re: preheat function) during the heating cycle so that there is no drain, or reduced drain, on the internal power supply. This can help in maintaining a higher charge level of the internal power supply and also increase the life of the internal power supply. Second, an external power supply can be used to charge the internal power supply. Third, connection to an external power supply (e.g., a car's cigarette lighter) enables a pre-heat function by which at least the earlier stages of the heating cycle are powered by the external power source instead of the internal power source. Again, this helps in maintaining a higher charge level (e.g., when the external power source is detached and the cushion is being used in a mobile manner. For example, a user could pre-heat the heating element by connecting the energy platform to a car's cigarette lighter. This connection could also be employed to simultaneously charge the internal power supply (e.g., if not already charged) and/or provide the pre-heat function. Then, the user may disconnect the external power supply and take the cushion to a sporting event or hunting stand (for example) and have a higher charge level of the internal power supply versus using the internal power supply to conduct all of the initial heating cycle. The external power supply may be “smart” in that it includes intelligence to monitor functions and data of other components (e.g., monitoring the charge level of the internal power supply). Optionally, the external power supply can be “dumb” and any necessary or desired intelligence can be included in the processor of the intelligent energy management platform, for example, or in another component.

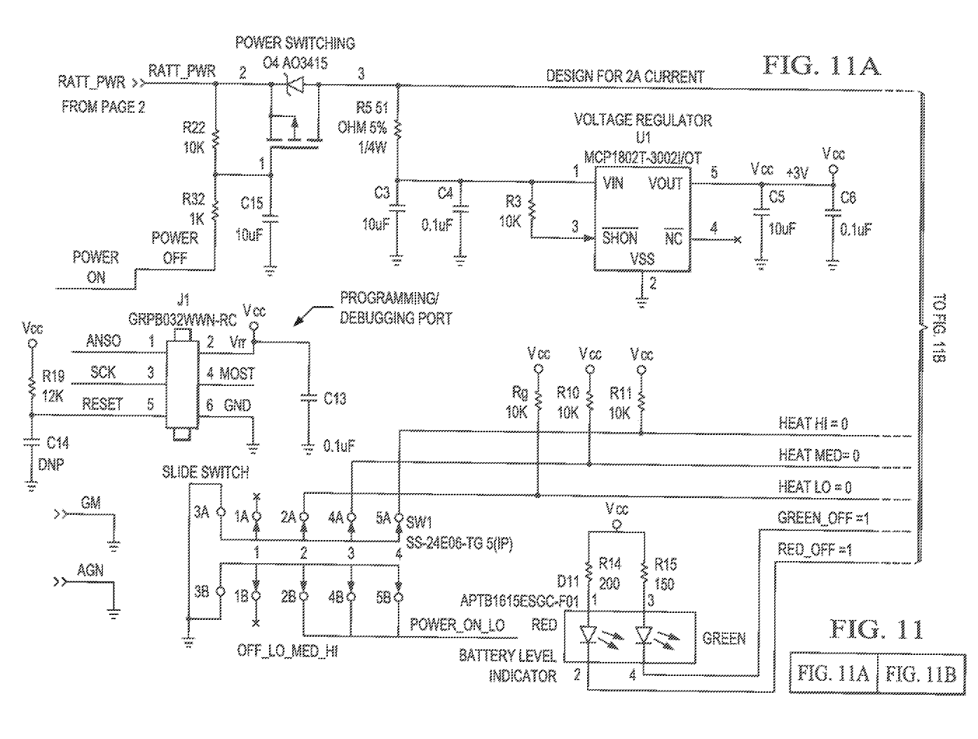

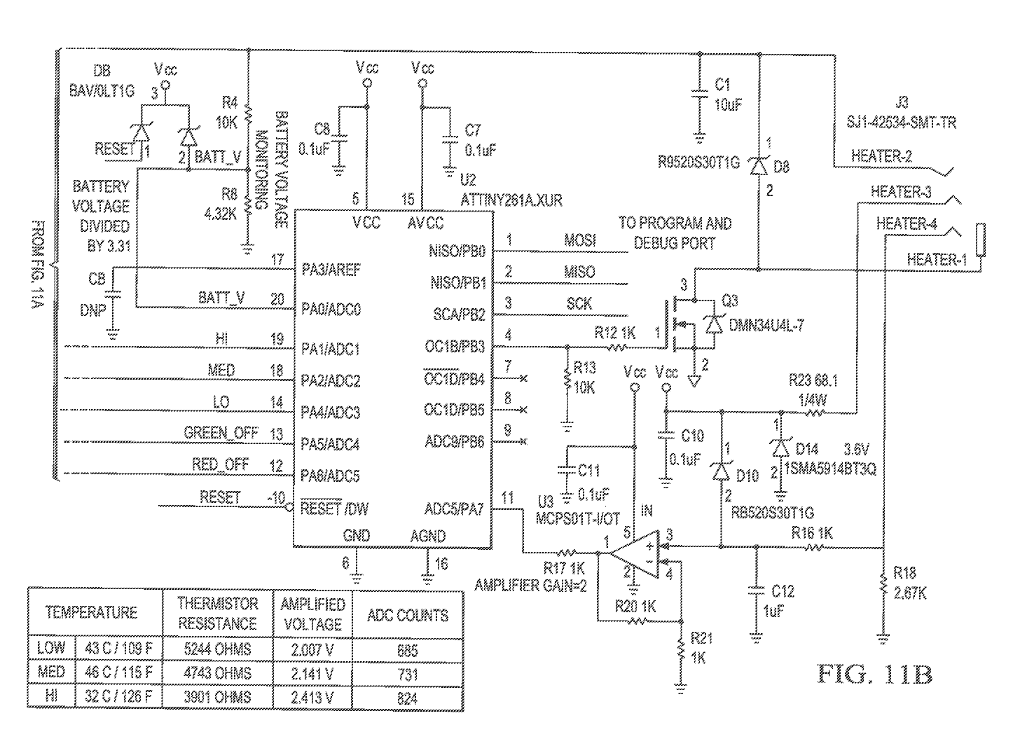

Other aspects, embodiments and features are illustrated in connection with FIG. 11A and FIG. 11B. FIG. 11A and FIG. 11B, for example, illustrates an electrical schematic of the aforementioned capabilities. Most parts in the circuit are well-defined and readily available off-the-shelf components, and are included here as exemplary of the overall design philosophy of the heated cushion device. FIG. 11A and FIG. 11B, in certain regards, illustrates a more detailed version of the circuitry discussed in connection with FIG. 1. It should be understood that the components of the circuitry may be changed, substituted, added to, omitted, altered, and reconfigured.

Imbedded in the electrical circuit logic, as shown for example in FIG. 1, are programmable attributes such as digital error feedback capabilities and control of thermal measurements, pulsing width modulated (variable duty cycle) circuit algorithms which are used to minimize energy consumption, multiple user temperature set points, microprocessor state tables for temperature and many other feedback and control settings, gain control, thermal measurements, temperature slew rate, and the like. In certain embodiments, the pulse width modulation (pwm) rate is 80% or higher when fully on and the temperature is stewing to the full temperature setting. Near the set point, the pwm is 10-40% duty cycle. At the set point the duty cycle is 10% or less.

In some embodiments, the intelligent heated cushion possesses an intelligently placed heater element inside which is removable in case it is defective.

In some embodiments, a thermistor or infrared sensing device is connected directly to the heater element to provide instantaneous thermal feedback to the microprocessor. This allows the capability of saving energy because no heat propagation away from the heater element is required. In addition, it also provides better accurate thermal regulation and resolution for the user and can prevent burns and other potential liabilities.

In some embodiments, both the heating element and thermistor are replaceable which provides longer use of the cushion.

In some embodiments, the cushion construction consists of an external cloth or other appropriate material which in cases the interior components. The internal construction from bottom to top consists of insulation, a unique MYLAR heat reflector which is aimed towards the top of the cushion, the intelligently placed heating element, and different thicknesses (R values) of insulation depending upon the particular application.

The reflector helps minimize the downward propagation of heat and provides a small R-value downward. The different R-values placed on the top of the cushion depend upon the application. For example, someone who is sitting on the cushion all the time requires a smaller R-value than someone who is leaving the cushion unattended and thereby allowing the heat to radiate from the top of the cushion.

In at least one embodiment the heated device may be designed with the capability for a pre-heat function from an external power source. The external power source may be any appropriate power source such as, for example, any DC voltage such as the cigarette lighter, USB port, solar, or other appropriate DC power source. The preheat function may be incorporated to bring the cushion up to operating temperature by using an external power source which is switched into the heater circuit. This capability minimizes battery drain such use of the device's batteries is limited to the time that the heated device is separated from the external power source. Of course, an AC power source may be used as well.

Also included in this intelligent heated cushion device is an external AC or DC connector which provides charging capabilities to the internal batteries. As well, the external connector could provide power to the battery. The combination also provides power to the electronics and heater to save battery life while simultaneously charging the batteries.

The pulsing current and corresponding duty cycles may be adjustable to save battery life.

Another feature is a component to set different thermal set points depending upon the user's requirements in the particular environment or particular application.

What is claimed is:

1. A device with efficient power routing, comprising:
a cover;
an interior material disposed within said cover;
an electrical element disposed within said cover;
a first power source connected to said electrical element, and operable to deliver energy to said electrical element; and
an intelligent energy management platform connected to said first power source and said electrical element, wherein the intelligent energy management platform selectively causes an interruption of energy from the first power source to the electrical element.

2. The device of claim 1, wherein the intelligent energy management platform comprises a pulsing circuit, the pulsing circuit configured to cause said first power source to supply pulsed power to the electrical element.

3. The device of claim 2, wherein the pulsed power is modulated.

4. The device of claim 3, wherein the modulation is pulse width modulation.

5. The device of claim 3, wherein the modulation is pulse frequency modulation.

6. The device of claim 3, wherein the modulation is pulse time modulation.

7. The device of claim 3, wherein the pulsed power is delivered to the electrical element during a powering cycle of the electrical element, and wherein the modulation percentage of the pulsed power is greater at an initial phase of the powering cycle and relatively less at a later phase of the powering cycle.

8. The device of claim 3, wherein the pulsed power is delivered to the electrical element during a powering cycle of the electrical element, and wherein pulsed power at a first modulation percentage is delivered to the electrical element at a first point in the powering cycle and pulsed power at a second modulation percentage is delivered to the electrical element at a second phase of the powering cycle.

9. The device of claim 3, wherein the electrical element is operable to receive energy from a second power source prior to being receiving energy from the first power source.

10. The device claim 1, further comprising a sensor for sensing at least one criterion of the electrical element and generating a signal associated with said criterion, the intelligent energy management platform comprising a comparator for comparing a reference signal to the generated signal of the sensor.

11. The device of claim 11, wherein the intelligent energy management platform uses the comparison to adjust one or more characteristics of the energy delivered to the electrical element.

12. A heated seat cushion, comprising:
an outer cover;
an interior material disposed within said outer cover;
a heating element disposed within said outer cover;
a first power source connected to said heating element, and operable to deliver energy to said heating element; and
an intelligent energy management platform connected to said first power source and said heating element, wherein the intelligent energy management platform selectively causes an interruption of energy from the first power source to the heating element.

13. The heated seat cushion of claim 12, further comprising a reflective layer disposed within the outer cover, the reflective layer reflecting heat from the heating element in a desired direction.

14. The heated seat cushion of claim 12, wherein the interior material is an insulation layer and the insulation layer is disposed between the heating element and the outer cover.

15. The heated seat cushion of claim 12, wherein the intelligent energy management platform further comprises:
an input electrically coupled to the power source;
an output electrically coupled to the at least one heating element;
and a pulsing circuit electrically connected to the at least one heating element, the pulsing circuit configured to provide output pulses to the at least one heating element at an on/off rate for providing modulated power to the at least one heating element.

16. The heated seat cushion of claim 15, further comprising a manual control coupled to the pulsing circuit and configured to set a desired on/off rate for providing modulated power to the at least one heating element.
